(19) United States
(12) Patent Application Publication
(10) Pub. No.: US 2025/0236981 A1
(43) Pub. Date: Jul. 24, 2025

(54) TWIN CRYSTAL COPPER MATERIAL AND HYBRID BONDING STRUCTURE

(71) Applicant: SHENZHEN INSTITUTES OF ADVANCED TECHNOLOGY CHINESE ACADEMY OF SCIENCES, Shenzhen (CN)

(72) Inventors: Zhi-Quan LIU, Shenzhen (CN); Zhe LI, Shenzhen (CN); Xiao LI, Shenzhen (CN); Li-Yin GAO, Shenzhen (CN); Rong SUN, Shenzhen (CN)

(73) Assignee: SHENZHEN INSTITUTES OF ADVANCED TECHNOLOGY CHINESE ACADEMY OF SCIENCES, Shenzhen (CN)

(21) Appl. No.: 18/698,773

(22) PCT Filed: Dec. 20, 2022
(86) PCT No.: PCT/CN2022/140433

§ 371 Date: Apr. 4, 2024

(30) Foreign Application Priority Data
Dec. 21, 2021 (CN) 202111574515.9
Dec. 21, 2021 (CN) 202111574709.9

(51) Int. Cl. C25D 3/38; C25D 5/50; C25D 7/12; C25D 21/10; H01L 23/498; H05K 1/09; H05K 1/11

(52) U.S. Cl. CPC C25D 3/38; C25D 5/50; C25D 7/12; C25D 21/10; H01L 23/49811; H01L 23/49833; H01L 23/49894; H05K 1/09; H05K 1/116; H05K 2201/042; H05K 2201/10242; H05K 2201/1031

(57) ABSTRACT

The present invention belongs to the technical field of high-performance metal materials and advanced electronic interconnection electroplating, and provides a twin crystal copper material which has preferred orientation of a (110) crystal plane, and includes twin crystal lamellas which are mainly distributed at an included angle of 45 degrees with a crystal grain growth direction; and a proportion of crystal grains with the twin crystal lamellas in total crystal grains of the twin crystal copper material is more than or equal to 50%, and/or a ratio of a volume of the twin crystal structure to a total volume of the twin crystal copper material is more than or equal to 50%. The twin crystal copper material provided by the present invention has more excellent structure thermal stability, and the twin crystal copper material shows the unique property that the proportion of the twin crystal lamellas does not decrease but increases.

### CROSS-REFERENCE TO RELATED APPLICATIONS

The application claims priority to Chinese patent application No. 202111574515.9 and No. 202111574709.9, filed on Dec. 21, 2021, the entire contents of which are incorporated herein by reference.

### TECHNICAL FIELD

The present invention belongs to the technical field of high-performance metal materials and electronic interconnection electroplating production, and relates to a twin crystal copper material and a hybrid bonding structure.

### BACKGROUND

Electroplated copper is a basic interconnection material for electronic circuits, and plays a role in signal and power transmission. The intensity of a traditional copper-based structural material is mainly improved through solid solution strengthening, fine grain strengthening, processing strengthening and the like, but the introduction of a large amount of impurities or defects often causes the drastic reduction of the ductility and the conductivity of the material. A twin crystal boundary is a special sub-boundary, and Ke Lu, etc., of Institute of Metal Research, Chinese Academy of Sciences discovered that the introduction of the high-proportion nanoscale twin crystal boundary can block dislocation movement as same as a common crystal boundary, but has an order of magnitude smaller than the common boundary in electron scattering capacity, so that the copper material is endowed with a series of advantageous characteristics such as ultrahigh intensity, and undegraded ductility and conductivity (for copper foil 16-25 μm thick, tensile intensity is more than 1000 MPa, and elongation is more than 13%). The nanoscale twin crystal is related to the control of a micro-nano organization structure of pure copper, so the nanoscale twin crystal has important application potentials in the field of high-performance electronic circuits.

A nanoscale twin crystal copper pulse or direct current electroplating process refers to the process of directly preparing a nanoscale twin crystal lamellar structure with a typical high proportion vertical to the growth direction by electrodeposition, namely a growth twin crystal.

The generation of the high-proportion nanometer twin crystal boundary depends on the selection of an electroplating process and an additive, and the formation mechanism thereof can be summarized as transient alternate changes of electric field application and pause (pulse electroplating) or additive adsorption and desorption (direct current electroplating) and the like, which can cause repeated stress to be temporarily accumulated in the electric crystallization process and released through twin crystal boundary nucleation, namely the formation of so-called growth twin crystal. Since copper deposition tends to grow along a (111) crystal plane with a low surface energy and the stacking fault energy is low, the twin crystal boundary grows directionally parallel to the (111) crystal plane. Compared with the common crystal boundary, the nanoscale twin crystal boundary has lower energy and is more stable, and the high-proportion nanoscale twin crystal boundary can inhibit the crystal boundary migration and the grain growth in the heat treatment or self-annealing recrystallization process, so that the nanoscale twin crystal structure shows better heat stability than common copper material structures such as nanoscale crystals, micron crystals, and coarse crystals. From the above, the material shows highly preferred orientation of the (111) crystal plane, and due to the introduction of the high-density nanoscale twin boundary, the material is endowed with ultrahigh intensity without compromising ductility and conductivity, so that the material is widely researched and reported.

At present, researches on the copper material with the high-proportion twin crystal boundary (a twin crystal copper material for short) are mainly carried out around preferred orientation of the (111) crystal plane and electroplating growth of the twin crystal, and a preparation method for a practical twin crystal copper material with preferred orientation of others like a (110) low-index crystal plane is not reported. The Chin. Chen team, National Chiao Tung University, China, reports an electroplating method ((Materials 2020,13,1211) for electroplating micron twin crystal copper with highly preferred orientation of the (110) crystal plane, and compared with electroplated nanoscale twin crystal copper with highly preferred orientation of the (111) crystal plane, a small crystal grain size (0.8 μm) and a small twin crystal lamella spacing (35 nm), the material also has twin crystal lamellas in a certain proportion, but the difference is that the crystal grain size is larger (4.4 μm), the twin crystal lamella spacing is wider (387 nm), and the twin crystal lamellas are parallel to the growth direction. The structure is annealed at 250° C. for 10 minutes, and obvious recrystallization occurs, crystal grains grow obviously, and the twin crystal lamellas disappear, so that the micron twin crystal copper material is shown only as a counter example due to poor structure thermal stability. In conclusion, no practical twin crystal copper material with the preferred orientation of others like the (110) low-index crystal plane and the preparation method thereof are reported, and the research on the material to obtain the practical twin crystal copper material is of great significance.

### SUMMARY

In view of the above problems in the prior art, the present invention aims to provide a twin crystal copper material, a preparation method and a use thereof.

In order to achieve the above objective, the present invention adopts the following technical solutions:

The twin crystal copper material has preferred orientation of a (110) crystal plane, the twin crystal copper material includes a twin crystal structure, the twin crystal structure includes twin crystal lamellas, and the twin crystal lamellas are mainly distributed at an included angle of 45 degrees with a crystal grain growth direction; and a proportion of crystal grains with the twin crystal lamellas in total crystal grains of the twin crystal copper material is more than or equal to 50%, and/or a ratio of a volume of the twin crystal structure to a total volume of the twin crystal copper material is more than or equal to 50%.

In the present invention, “mainly” in “the twin crystal lamellas are mainly distributed at an included angle of 45 degrees with a crystal grain growth direction”. refers to more than 50% (e.g., 52%, 55%, 60%, 65%, 70%, 75%, 80%, 85%, 90%, 92%, 95%, 96%, 98%, 99%, or 100%) of the twin crystal lamellas. The “included angle” refers to an acute included angle between the twin crystal lamellas and the crystal grain growth direction.

In the present invention, the proportion of the crystal grains with the twin crystal lamellas in the total crystal grains of the twin crystal copper material may be, for example, 50%, 55%, 60%, 65%, 70%, 75%, 80%, 85%, 90%, 95%, 97%, 98%, 99%, or the like.

In the present invention, the ratio of the volume of the twin crystal structure to the total volume of the twin crystal copper material may be, for example, 50%, 52%, 55%, 60%, 63%, 65%, 70%, 75%, 80%, 85%, 88%, 90%, 95%, 97%, 98%, 99%, or the like.

The twin crystal copper material provided by the present invention is annealed twin crystal copper with preferred orientation of the (110) crystal plane, wherein a high-proportion twin crystal boundary exists stably, compared with electroplated micron twin crystal copper with highly preferred orientation of the (110) crystal plane, the twin crystal copper material has more excellent structure thermal stability, the crystal grains grow up normally within a common heat treatment temperature range (such as 200-400° C.) in electronic materials, and the twin crystal copper material shows the unique property that the proportion of the twin crystal lamellas does not decrease but increases.

The twin crystal copper material of the present invention can be suitable for the relevant fields of electro-coppering represented by the manufacturing and packaging of integrated circuits and circuit boards, and optimizes the stability of a structure of an electro-coppering material in the heat treatment, namely, the twin crystal structure is generated and stabilized by introducing the heat treatment, and the abnormal growth of the crystal grains and the decline of the material intensity in the process are inhibited.

The following as preferred technical solutions of the present invention are not intended to limit the technical solutions provided by the present invention, and the technical objectives and beneficial effects of the present invention can be better achieved and implemented by the following preferred technical solutions.

Further, XRD diffraction analysis is carried out on the twin crystal copper material, and an intensity ratio of (220)/(111) diffraction peaks is more than 2. For example, the intensity ratio is 3, 4, 5, 6, 7, 8, 9 or 10, the higher the intensity ratio is, the more grains are directionally grown along the (110) crystal plane, and the stronger the 45-degree growth orientation of the twin lamellas and the crystal grain growth direction is.

Further, the twin crystal copper material is obtained by carrying out heat treatment on a pre-electroplated copper material with preferred orientation of a (111) crystal plane, wherein a heat treatment temperature is more than or equal to 200° C. Exemplarily, the heat treatment temperature may be 200° C., 220° C., 240° C., 260° C., 300° C., 350° C., 400° C. or 450° C.

In the present invention, the pre-electroplated copper material refers to an electroplated copper material which is not subjected to annealing treatment.

By carrying out heat treatment on the pre-electroplated copper material, the preferred orientation of the (111) crystal plane may be converted into the preferred orientation of the (110) crystal plane, along with formation of high-proportion annealed twin crystals, the twin crystal lamellas are mainly distributed at an included angle of 45 degrees with the crystal grain growth direction, and the obtained twin crystal copper material shows excellent thermal stability.

In an alternative embodiment, a heat treatment mode is annealing. A schematic diagram of the change in a product structure before and after annealing refers to FIG. 6.

One objective of the present invention is to provide a preparation method for a twin crystal copper material.

The preparation method for the twin crystal copper material includes the following steps:
(1) preparing a plating solution
the plating solution including copper ions, sulfuric acid, chloride ions, an additive and water, the additive including an inhibitor and an auxiliary agent, and the auxiliary agent being at least one selected from organic sulfonates;
(2) carrying out direct current electroplating
immersing an anode and a cathode as a conductive substrate into the plating solution, and electroplating to obtain a pre-electroplated copper material; and
(3) carrying out heat treatment on the pre-electroplated copper material with a heat treatment temperature of more than or equal to 200° C., to obtain the twin crystal copper material.

In the present invention, the heat treatment temperature is more than or equal to 200° C., for example, 200° C., 225° C., 260° C., 280° C., 300° C., 320° C., 350° C., 370° C., 400° C., 450° C., 500° C., 550° C., 600° C., 650° C., 700° C. or 750° C.

The present invention opens up a novel preparation way for the twin crystal copper material with highly preferred orientation of the (110) crystal plane and an annealed twin crystal type. Different from that growth twin crystals are formed by electroplating at one step, in the method of the present invention, the formation of the annealed twin crystals includes two steps of copper pre-electroplating and annealing treatment, specifically, by utilizing chemical regulation and control of a pre-electroplating additive combination, the pre-electroplated copper material shows certain preferred orientation of the (111) crystal plane and does not form a growth twin crystal with high proportion and vertical to a growth direction, the pre-electroplated copper material is converted into preferred orientation of the (110) crystal plane after heat treatment (for example, annealing for 1 hour) at the temperature of more than or equal to 200° C., and twin crystal lamellas are mainly distributed at an included angle of 45 degrees with a crystal grain growth direction along with the formation of the high-proportion annealed twin crystals. The crystal grains grow up normally within a common heat treatment temperature range, thereby showing excellent thermal stability.

In the method of the present invention, the pre-electroplating additive combination has important influence on a structure of the pre-electroplated material, namely, the deposition rate can be reduced by adding the inhibitor into the plating solution, and the coarse and non-compact crystallization is avoided; the deposition rate can be improved by adding the auxiliary agent into the plating solution; and the dynamic controllable desorption of the double electric layer inhibitor is realized by the competitive action of the auxiliary agent and the inhibitor, and an electro-crystallization defect concentration necessary for hatching an annealed twin crystal boundary is introduced.

The method of the present invention directly obtains the growth twin crystals by replacing conventional electroplating with the annealing twin crystals, can ensure the stable existence of the high-proportion twin crystal boundary in the heat treatment process, and opens up a new idea for the preparation and the application of the twin crystal copper material with the highly preferred orientation of the (110) crystal plane.

Further, in step (1), the organic sulfonates include at least one of polystyrene sulfonate, polyethylene sulfonate, alkyl sulfonate and alkylbenzene sulfonate.

Further, a molecular weight of the polystyrene sulfonate and a molecular weight of the polyethylene sulfonate are independently 1000-100000, for example, 1000, 3000, 5000, 8000, 10000, 12500, 15000, 17000, 20000, 25000, 35000, 40000, 50000, 60000, 70000, 80000, or 100000.

Further, carbon atom numbers of the alkyl sulfonate and the alkylbenzene sulfonate are more than or equal to 12. Exemplarily, the carbon atom numbers may be 12, 13, 14, 15, 16, 17, or 20. It should be noted that the carbon atom numbers of the alkyl sulfonate and the alkylbenzene sulfonate may be same or different.

Further, in step (1), a concentration of the auxiliary agent in the plating solution is 10-500 ppm. Exemplarily, the concentration of the auxiliary agent in the plating solution is 10 ppm, 20 ppm, 30 ppm, 40 ppm, 50 ppm, 60 ppm, 70 ppm, 80 ppm, 100 ppm, 150 ppm, 200 ppm, 230 ppm, 260 ppm, 300 ppm, 350 ppm, 400 ppm, or 500 ppm.

Further, in step (1), the inhibitor is gelatin, and a coagulation value of the gelatin is 10-300 bloom. Exemplarily, the coagulation value of the gelatin is 10 bloom, 20 bloom, 30 bloom, 50 bloom, 70 bloom, 80 bloom, 100 bloom, 125 bloom, 150 bloom, 180 bloom, 200 bloom, 225 bloom, 240 bloom, 260 bloom, or 300 bloom.

Further, in step (1), a concentration of the inhibitor in the plating solution is 5-200 ppm. Exemplarily, the concentration of the inhibitor in the plating solution is 5 ppm, 10 ppm, 20 ppm, 30 ppm, 40 ppm, 50 ppm, 60 ppm, 70 ppm, 80 ppm, 100 ppm, 120 ppm, 150 ppm, 180 ppm, or 200 ppm.

Further, in step (1), a concentration of the copper ions in the plating solution is 20-70 g/L. Exemplarily, the concentration of the copper ions in the plating solution is 20 g/L, 30 g/L, 40 g/L, 50 g/L, 60 g/L, or 70 g/L.

In the actual preparation process, the copper ions may be derived from copper salts, for example, by selecting copper sulfate pentahydrate ((CuS04·5H20).

Further, in step (1), a concentration of the sulfuric acid in the plating solution is 20-200 g/L. Exemplarily, the concentration of the sulfuric acid in the plating solution is 20 g/L, 25 g/L, 30 g/L, 35 g/L, 40 g/L, 50 g/L, 60 g/L, 70 g/L, 80 g/L, 100 g/L, 120 g/L, 150 g/L, 160 g/L, 180 g/L, or 200 g/L.

In the actual preparation process, the sulfuric acid may be derived from concentrated sulfuric acid, for example, by selecting dilute 96-98 wt % concentrated sulfuric acid (H2S04).

Further, in step (1), a concentration of the chloride ions in the plating solution is 20-80 ppm. Exemplarily, the concentration of the chloride ions in the plating solution is 20 ppm, 30 ppm, 40 ppm, 45 ppm, 50 ppm, 60 ppm, 70 ppm, or 80 ppm.

In the actual preparation process, the chloride ions may be derived from hydrochloric acid.

Further, in step (2), the anode is selected from a phosphor-copper anode, and a phosphor content in the phosphor-copper anode is 0.03-0.075 wt %. Exemplarily, the phosphorus content in the phosphorus-copper anode is 0.03 wt %, 0.04 wt %, 0.05 wt %, 0.06 wt %, or 0.07 wt %.

In an alternative embodiment, the phosphorus-copper anode is subjected to electrolytic activation treatment, the conditions of the electrolytic activation treatment are not specifically limited in the present invention, and the phosphorus-copper anode may be electrolyzed in a plating solution containing only copper ions, sulfuric acid and chloride ions at a constant current of 1 A/dm2 for 30 min, or other electrolytic activation parameters commonly used in the art may be adopted, but it needs to be ensured that a uniform black phosphide film is formed on the surface of the material.

Further, in step (2), an electroplating temperature is 20-50° C. Exemplarily, in step (2), the electroplating temperature is 20° C., 23° C., 25° C., 28° C., 30° C., 35° C., 40° C., 45° C., or 50° C.

Further, in step (2), the electroplating is carried out under a constant temperature condition.

Further, in step (2), a current density of the electroplating is 0.5-25 A/dm2. Exemplarily, the current density of the electroplating is 0.5 A/dm2, 1 A/dm2, 1.5 A/dm2, 2 A/dm2, 3 A/dm2, 4 A/dm2, 5 A/dm2, 6 A/dm2, 7 A/dm2, 8 A/dm2, 8.5 A/dm2, 9 A/dm2, 10 A/dm2, 11 A/dm2, 12 A/dm2, 15 A/dm2, 18 A/dm2, 20 A/dm2, 21 A/dm2, 22 A/dm2, 23 A/dm2, or 25 A/dm2.

Further, in step (2), an electroplating time is 20-1800 min. Optionally, the electroplating time is 20 min, 30 min, 40 min, 60 min, 80 min, 90 min, 120 min, 150 min, 180 min, 200 min, 240 min, 280 min, 300 min, 350 min, 450 min, 500 min, 550 min, 600 min, 700 min, 800 min, 850 min, 900 min, 1000 min, 1100 min, 1200 min, 1250 min, 1300 min, 1400 min, 1500 min, 1600 min, 1700 min, or 1750 min.

The electroplating solution is further stirred in the electroplating process in step (2), wherein the stirring includes at least one of circulating jet flow, air stirring, magnetic stirring and mechanical stirring.

The heat treatment in step (3) includes annealing treatment, including heating the pre-electroplated copper material from a room temperature to the heat treatment temperature in an inert atmosphere, preserving heat for a certain time, and finally recovering to the room temperature, wherein the heat treatment temperature is 200-750° C., the heating rate is 1-50° C./min, and the heat preservation time is 20-1200 min.

In the present invention, the room temperature means 20-25° C.

Optionally, the heat treatment temperature is 200° C., 225° C., 260° C., 280° C., 300° C., 320° C., 350° C., 370° C., 400° C., 450° C., 500° C., 550° C., 600° C., 650° C., 700° C., or 750° C. Optionally, the heat treatment temperature is 200-400° C.

Optionally, the heat preservation time is 20 min, 30 min, 40 min, 60 min, 80 min, 90 min, 120 min, 150 min, 180 min, 200 min, 240 min, 280 min, 300 min, 350 min, 450 min, 500 min, 550 min, 600 min, 700 min, 800 min, 850 min, 900 min, 1000 min, 1100 min or 1200 min.

In the present invention, gas in the inert atmosphere includes, but is not limited to, at least one of nitrogen, helium, argon, and hydrogen.

The type of the conductive substrate in the present invention is not particularly limited, for example, the conductive substrate may be selected from copper, titanium, tantalum, gold, tungsten, diamond, nickel, and an alloy formed by at least two of the above metals, and may also be a plate, a film, a printed wiring board, a wafer seed crystal layer, etc. made of the above alloy.

A preparation method for the conductive substrate is not limited in the present invention, for example, the conductive substrate may be prepared by a method of electroplating, electroless plating, sputtering, fusion casting, and the like.

In the present invention, the conductive substrate may be pre-treated before use, for example, for a substrate with greasy dirt and oxide on the surface, the substrate may be subjected to sufficient degreasing, pickling and washing processes before use to completely remove the greasy dirt and oxide on the surface, thereby exposing a fresh and clean substrate surface.

The degreasing process may be performed by selecting a 10 wt % sodium hydroxide

(NaOH) solution for soaking and stirring or other degreasing modes commonly used in the field.

The pickling process may be performed by selecting a 5 wt % sulfuric acid (H2S04) solution for soaking and stirring or other oxide removing modes commonly used in the field.

One objective of the present invention is to provide a preparation method for a twin crystal copper material.

The preparation method for the twin crystal copper material includes the following steps:
(1) preparing a plating solution
dissolving copper salt, sulfuric acid, chloride, an inhibitor and an auxiliary agent in water, and fully and uniformly dispersing to obtain the plating solution, wherein the plating solution includes 20-70 g/L of the copper ions, 20-200 g/L of the sulfuric acid, 20-80 ppm of the chloride ions, 5-200 ppm of the inhibitor, 10-500 ppm of the auxiliary agent and the balance of water, the inhibitor includes gelatin, and the auxiliary agent is at least one selected from the organic sulfonates;
(2) carrying out direct current electroplating
immersing an anode and a cathode as a conductive substrate into the plating solution, and electroplating at a constant current under a temperature of 20-50° C. to obtain a pre-electroplated copper material, wherein a current density is 0.5-25 A/dm2, and the electroplating time is 20-1800 min; and
(3) heating the pre-electroplated copper material until the temperature is more than or equal to 200° C. and keeping the temperature for 20-1200 min, to obtain the twin crystal copper material.

One objective of the present invention is to provide a use of any one twin crystal copper material described above, the twin crystal copper material is used in an electronic circuit interconnection scenario, and the electronic circuit interconnection scenario includes integrated circuit packaging or printed wiring board manufacturing.

One objective of the present invention is to provide a hybrid bonding structure.

The hybrid bonding structure includes a first substrate and a second substrate which are oppositely disposed, a first bonding layer is disposed on the first substrate, a second bonding layer is disposed on the second substrate, and the first bonding layer and the second bonding layer are bonded to form a bonding interface; and

copper bonding points are disposed in the first bonding layer and/or the second bonding layer, and the copper bonding points are the twin crystal copper material according to claim 1.

The copper bonding points are disposed in the first bonding layer and/or the second bonding layer, the copper bonding points have preferred orientation of a (110) crystal plane, the twin crystal copper material includes a twin crystal structure, the twin crystal structure includes twin crystal lamellas, and the twin crystal lamellas are mainly distributed at an included angle of 45 degrees with a crystal grain growth direction; and a proportion of crystal grains with the twin crystal lamellas in total crystal grains of the twin crystal copper material is more than or equal to 50%, and/or a ratio of a volume of the twin crystal structure to a total volume of the twin crystal copper material is more than or equal to 50%.

The hybrid bonding structure provided by the present invention can effectively improve the bonding force between chips, and can ensure better electrical connection, the copper bonding points have excellent structure thermal stability and mechanical properties (especially the high-temperature mechanical property), the hybrid bonding structure has high mechanical intensity and toughness, and the service reliability is improved.

The use of the copper bonding points with the specific composition avoids the recrystallization of the copper bonding points in the thermocompression bonding process and the subsequent processes such as reflow soldering or heat treatment, thereby solving the problems of insufficient mechanical intensity, poor service reliability and the like caused by the recrystallization.

The following as preferred technical solutions of the present invention are not intended to limit the technical solutions provided by the present invention, and the technical objectives and beneficial effects of the present invention can be better achieved and implemented by the following preferred technical solutions.

Further, a height of the copper bonding points is 0.5-500 microns. Optionally, the height of the copper bonding points is 0.5 micron, 0.8 micron, 1 micron, 2 microns, 3 microns, 5 microns, 8 microns, 10 microns, 15 microns, 20 microns, 25 microns, 30 microns, 35 microns, 40 microns, 45 microns, 50 microns, 55 microns, 60 microns, 65 microns, 70 microns, 80 microns, 90 microns, 100 microns, 115 microns, 130 microns, 140 microns, 150 microns, 160 microns, 180 microns, 200 microns, 220 microns, 240 microns, 265 microns, 280 microns, 300 microns, 320 microns, 340 microns, 350 microns, 375 microns, 385 microns, 400 microns, 405 microns, 420 microns, 450 microns, 470 microns, 480 microns, 490 microns, or the like, preferably 30-300 microns, within which an electro-crystallized microstructure is uniformly stable, ensuring that high-proportion annealed twin crystals are generated.

Materials of the first substrate and the second substrate are not particularly limited by the present invention, and the materials of the first substrate and the second substrate independently include silicon, a compound, ceramic, or glass.

Optionally, the first bonding layer includes a dielectric layer and copper bonding points disposed in the dielectric layer at intervals, and the copper bonding points are exposed out of a surface of the first bonding layer for bonding.

Optionally, the second bonding layer includes a dielectric layer and copper bonding points disposed in the dielectric layer at intervals, and the copper bonding points are exposed out of a surface of the second bonding layer for bonding.

Optionally, materials of the dielectric layer in the first bonding layer and the dielectric layer in the second bonding layer are independently selected from at least one of organic polymers or oxides.

One objective of the present invention is to provide a preparation method for a hybrid bonding structure.

The preparation method for the hybrid bonding structure includes the following steps:
(1) providing a first substrate and a second substrate, forming a first bonding layer on the first substrate, and forming a second bonding layer on the second substrate, wherein copper bumps are disposed in the first bonding layer and/or the second bonding layer, and the copper bumps are the pre-electroplated copper material; and
(2) oppositely disposing the first substrate and the second substrate, carrying out thermocompression bonding, and bonding the first bonding layer and the second bonding layer to form a bonding interface to obtain the hybrid bonding structure.

A temperature of the thermocompression bonding is more than or equal to 200° C.

In the method of the present invention, the first substrate and the second substrate are disposed oppositely, which means that the first bonding layer on the first substrate and the second bonding layer on the second substrate are disposed oppositely.

In an alternative embodiment, the copper bumps in the first bonding layer correspond to and make contact with the copper bumps in the second bonding layer one to one.

Optionally, the temperature of the thermocompression bonding is 200° C., 220° C., 240° C., 260° C., 300° C., 350° C., 400° C., or 450° C. The thermocompression bonding at this temperature is equivalent to annealing treatment, under which an annealed twin crystal structure (i.e., a twin crystal structure) can be continuously formed during the annealing treatment.

According to the method of the present invention, the disposed copper bumps have certain preferred orientation of a (111) crystal plane and a growth twin crystal boundary parallel to a deposition direction, the annealed twin crystal structure may be formed after thermocompression bonding (for example, the temperature of the thermocompression bonding is 200° C.) to obtain copper bonding points, the copper bonding points have preferred orientation of the (110) crystal plane, twin crystal lamellas are distributed at an included angle of 45 degrees with the crystal grain growth direction, a proportion of crystal grains with the twin crystal lamellas in total crystal grains of the copper bonding points is more than or equal to 50%, and/or a ratio of a volume of the twin crystal structure in a total volume of the copper bonding points is more than or equal to 50%.

According to the method of the present invention, the copper bumps with certain preferred orientation of the (111) crystal plane are converted into the copper bonding points with preferred orientation of the (110) crystal plane through thermocompression bonding treatment, the copper bonding points have excellent structure thermal stability, abnormal growth of the crystal grains is not seen along with the increase of an annealing temperature within a common heat treatment temperature range (about 200 to 400° C.) of micro-electronic interconnection, the proportion of annealed twin crystals in the crystal grains is increased, and the intensity and toughness of the copper bumps are enhanced, so that the copper bonding points are different from a micron crystal structure and growth twin crystal structure bumps with annealing softening toughening, and show a unique annealing reinforcement toughening characteristic.

The method of the present invention improves the structure thermal stability and high-temperature mechanical property of the bonded copper bumps (namely the copper bonding points), and increases the service reliability of the hybrid bonding structure.

As a preferable technical solution of the method of the present invention, in step (1), the first substrate and/or the second substrate is prepared according to the following method, which includes the following steps:
(I) preparing a substrate with a conductive layer;
(II) carrying out patterning treatment on a surface of the conductive layer of the substrate by utilizing a photoetching process, forming a photoresist pattern on the conductive layer, and exposing the conductive layer at the part without a photoresist; (III) filling the part without the photoresist to form copper bumps;
(IV) removing the redundant photoresist and the conductive layer; and
(V) depositing a dielectric layer, and carrying out chemical mechanical polishing (CMP) treatment on the surface of a wafer to expose the copper bumps.

The substrate in step (I) is the first substrate or the second substrate.

In the present invention, the photoetching process in step (II) is to form the pattern by the photoresist through exposure, the pattern refers to a region covered with the photoresist, and the region not covered with the photoresist is subsequently used for being filled to form the copper bumps, for example, a pre-electroplated copper material with preferred orientation of a (111) crystal plane is formed in an electroplating manner to serve as the copper bumps.

In the present invention, the purpose of carrying out CMP treatment on the surface of the wafer in step (V) is to polish off the redundant dielectric layer to expose the surface of the copper bumps (e.g., copper pillars), and another important role is to make the bonding surfaces completely coplanar and achieve the roughness requirement required for bonding.

In an alternative embodiment, the conductive layer in step (I) may be an adhesion layer and a seed layer obtained by vapor deposition; or may be a through-silicon-via (TSV) top filled with a conductive metal. Exemplarily, the material of the adhesion layer may be at least one of tantalum, titanium, or nitride thereof. The material of the seed layer is copper. The conductive metal is copper.

In an alternative embodiment, the TSV is circular in shape and has a diameter of 15-100 microns, for example, 15 microns, 20 microns,
30 microns, 40 microns, 50 microns, 60 microns, 70 microns, 80 microns, 90 microns, 100 microns, etc.

In an alternative embodiment, each substrate contains one or more independent TSV structures which are arranged in a certain order on the substrate.

Optionally, a thickness of the photoresist formed in step (II) is 1-500 microns. Optionally, the thickness of the photoresist formed in step (II) is 1 micron, 3 microns, 5 microns, 8 microns, 10 microns, 15 microns, 20 microns, 25 microns, 30 microns, 35 microns, 40 microns, 45 microns, 50 microns, 60 microns, 80 microns, 100 microns, 120 microns, 130 microns, 140 microns, 150 microns, 165 microns, 180 microns, 200 microns, 220 microns, 240 microns, 260 microns, 280 microns, 300 microns, 325 microns, 350 microns, 375 microns, 400 microns, 430 microns, 460 microns, or 500 microns.

The method for depositing the dielectric layer in step (V) is not particularly limited by the present invention, for example, the material of the dielectric layer is Benzocyclobutene (BCB), SU-8, Polyimide (PI), etc., and the deposition method is spin coating; and in another example, the dielectric layer is SiO₂, and the deposition method is physical vapor deposition.

Optionally, a thickness of the dielectric layer should be slightly higher than that of the copper bumps (e.g., the copper pillars).

In an alternative embodiment, in step (V), after CMP treatment, the wafer is subjected to plasma cleaning treatment. Through plasma cleaning treatment, remnants generated by CMP can be eliminated, and meanwhile, the bonding surfaces can be activated, and the bonding difficulty is reduced.

In an alternative embodiment, plasma cleaning parameters are hydrogen 70-100 sccm, oxygen 10-50 sccm, power 500-800 W, and time 60-600 s. Optionally, a flow rate of the hydrogen is 70 sccm, 80 sccm, 85 sccm, 90 sccm, or 100 sccm. Optionally, a flow rate of the oxygen is 10 sccm, 20 sccm, 30 sccm, 40 sccm, or 50 sccm. Optionally, the power is 500 W, 550 W, 600 W, 650 W, 700 W, or 800 W. Optionally, the time is 60 s, 80 s, 100 s, 125 s, 150 s, 160 s, 180 s, 200 s, 220 s, 260 s, 300 s, 320 s, 350 s, 400 s, 425 s, 450 s, 480 s, 500 s, 550 s, or 600 s.

As a preferable technical solution of the method of the present invention, in step (1), the first substrate and/or the second substrate is prepared according to the following method, which includes the following steps:
(I) providing a silicon substrate with a TSV structure, wherein the TSV is filled with a conductive metal;
(II) coating a dielectric layer on one surface of the silicon substrate, and windowing at the position with the TSV structure by using a photoetching process to expose the conductive metal;
(III) filling the position where the conductive metal is exposed to form copper bumps; and
(IV) carrying out CMP treatment on the surface of a wafer,
wherein the silicon substrate in step (II) is a first substrate or a second substrate.

The use of the photoetching process for windowing in step (II) of the present invention is well known in the art and those skilled in the art can refer to the disclosure of the prior art for performing photoetching windowing.

In the present invention, CMP treatment is carried out on the surface of the wafer in step (IV), so that the copper bumps and the dielectric layer can be coplanar and achieve lower roughness.

In an alternative embodiment, in the silicon substrate with the TSV structure provided in step (II), the TSV is circular in shape and has a diameter of 15-100 microns, such as 15 microns, 20 microns, 30 microns, 40 microns, 50 microns, 60 microns, 70 microns, 80 microns, 90 microns, or 100 microns.

In an alternative embodiment, each substrate contains one or more independent TSV structures which are arranged in a certain order on the substrate.

In an alternative embodiment, the conductive metal is copper.

Optionally, a direct current electroplating technology is adopted to fill the copper bumps, the pre-electroplated copper material in step (1) is prepared by electroplating, and the electroplating method includes the steps of (1) preparing the plating solution and (2) carrying out direct current electroplating in any one preparation method for the twin crystal copper material described above.

Optionally, a heating rate of a temperature rise to the temperature of the thermocompression bonding is 0.5-20° C./min. Optionally, the heating rate of the temperature rise to the temperature of the thermocompression bonding is 0.5° C./min, 1° C./min, 2° C./min, 3° C./min, 5° C./min, 8° C./min, 10° C./min, 12° C./min, 15° C./min, 17° C./min, or 20° C./min.

Optionally, during the thermocompression bonding, an applied pressure intensity is 0.5-3 MPa. Optionally, during the thermocompression bonding, the applied pressure intensity is 0.5 MPa, 1 MPa, 1.5 MPa, 2 MPa, 2.5 MPa, or 3 MPa.

Optionally, an atmosphere of the thermocompression bonding is an inert atmosphere or vacuum. Optionally, the gas in the inert atmosphere may be one or a mixed gas of more of nitrogen, helium, and hydrogen.

Optionally, a thermocompression bonding time is 1-2 hours. Optionally, the thermocompression bonding time is 1 hour, 1.2 hours, 1.5 hours, 1.7 hours, or 2 hours.

Compared with the prior art, the present invention has the following beneficial effects:

(1) The twin crystal copper material provided by the present invention is annealed twin crystal copper with preferred orientation of the (110) crystal plane, wherein the high-proportion twin crystal boundary exists stably, compared with electroplated micron twin crystal copper with highly preferred orientation of the (110) crystal plane, the twin crystal copper material has more excellent structure thermal stability, the crystal grains grow up normally within a common heat treatment temperature range (such as 200-400° C.) in the field of electronic materials, and the twin crystal copper material shows the unique property that the proportion of the twin crystal lamellas does not decrease but increases.

(2) The preparation method of the present invention is based on the electroplated copper process and the heat treatment technology, can change the preferred orientation of the electroplated copper crystal plane and generate the high-proportion annealed twin crystal structure by simple means such as the regulation and control of the additive combination of the electroplating solution and the heat treatment on a plating layer, has the advantages of easy operation, low cost, strong practicability, suitability for industrialized popularization and the like, can be suitable for the electroplated copper related fields represented by the manufacturing and packaging of integrated circuits and circuit boards, and optimizes the stability of a heat treatment structure of the electroplated copper material.

(3) In the hybrid bonding structure provided by the present invention, the copper bonding points have the high-proportion annealed twin crystals and show the characteristic of annealing reinforcement, namely, the intensity and the toughness of an interconnection material are increased along with the increase of the annealing temperature, and the copper bonding points are different from electroplated copper bumps of a common micron crystal structure with annealing softening, so that the overall mechanical property of the bonding interconnection structure is improved. Meanwhile, the annealed twin crystal lamellas have the characteristic of higher thermal stability, the proportion of the annealed twin crystal boundary does not decrease but increases within the common heat treatment temperature range (about 200-400° C.) of micro-electronic interconnection, and the crystal grains grow up normally. Therefore, the technical solutions of the present invention can reduce the failure risk of the bonding points in the bonding process or after multiple times of reflow and heat treatment processes, thereby enhancing the service reliability of the interconnection structure and a device.

(4) The preparation method for the hybrid bonding structure of the present invention is based on copper bump electroplating filling and thermocompression bonding technologies, enhances the mechanical property of the copper bump interconnection structure only through the microstructure engineering of the electroplated copper material, has the advantages of easy operation, low cost, compatible process and the like, and is suitable for industrial popularization in the field of microelectronic packaging.

### BRIEF DESCRIPTION OF DRAWINGS

FIG. 1 is a cross-sectional focused ion beam microscopic topography of an annealed twin crystal plating layer material of Example 1;

FIG. 2 is a surface X-ray diffraction pattern of the annealed twin crystal plating layer material of Example 1 before and after annealing;

FIG. 3 is a cross-sectional focused ion beam microscopic topography of an annealed twin crystal plating layer material of Example 2;

FIG. 4 is a cross-sectional focused ion beam microscopic topography of a growth twin crystal plating layer material of Comparative example 1;

FIG. 5 is a plating surface X-ray diffraction pattern of the growth twin crystal plating layer material of Comparative example 1 when not annealed;

FIG. 6 is a schematic diagram of the change in a product structure before and after annealing in an embodiment of the present invention;

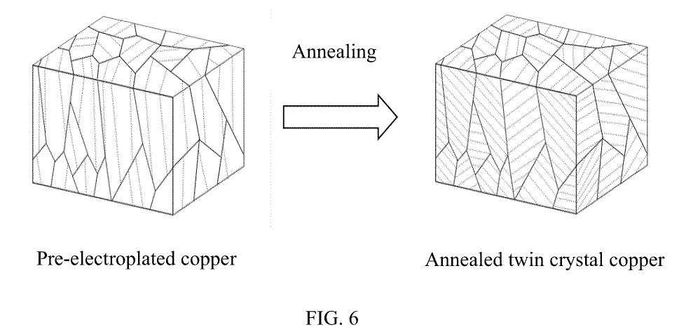

FIG. 7 is a flow chart of preparing a hybrid bonding structure in an example of the present invention; and

FIG. 8 is a flow chart of preparing a hybrid bonding structure in another example of the present invention;

wherein 01—first substrate, 02—composite layer of adhesion layer and seed layer, 03—photoresist, 04—first copper bump

05—polyimide dielectric layer, 06—second substrate, 07—first silicon substrate, 08—conductive metal, 09—benzocyclobutene dielectric layer, 10—second copper bump, 11—second silicon substrate, and 12—second silicon substrate.

### DETAILED DESCRIPTION OF THE EMBODIMENTS

In order to make the aforementioned objectives, features and advantages of the present invention more comprehensible, specific embodiments accompanied with figures are described in detail below, but are not to be construed as limiting the implementable range of the present invention.

### Example 1

The present example provides a twin crystal copper material, which is prepared by the following method. The method includes the following steps:

### (1) Preparation of a Plating Solution

The electroplating solution is prepared and uniformly dispersed by adopting the following components of 30 g/L of copper ions, 30 g/L of sulfuric acid, 30 ppm of chloride ions, 80 ppm of an inhibitor, 300 ppm of an auxiliary agent and 250 mL of pure water, wherein the inhibitor is gelatin with a coagulation value of 100 bloom, and the auxiliary agent is sodium polystyrene sulfonate with a molecular weight of 40000.

### (2) Direct Current Electroplating

a. Cathode pretreatment. A high-purity titanium plate is used as a cathode, and subjected to the processes of alkali washing, acid washing and water washing sequentially.

b. Direct current electroplating. The titanium plate as the cathode and phosphor copper as an anode (a phosphor content is 0.05 wt %) are immersed in the plating solution, magnetic stirring is carried out at 300 rpm, and the plating solution is controlled to be constant at 25° C. Then, a rectifier is connected in, and plating is carried out for 120 min at a current density of 3 A/dm2.

c. Plating layer post-treatment. A plating layer is taken out from the plating solution, separated from a substrate (titanium plate), and repeatedly washed by using pure water to remove a residual plating solution, and finally the surface of the plating layer is dried by using compressed air.

### (3) Annealing Treatment.

The plating layer is put in a tube furnace, a nitrogen protective atmosphere is introduced, the temperature in the furnace is increased from the room temperature to 350° C. at the speed of 10° C./min and kept for 1 hour, then the furnace is naturally cooled, and the plating layer is taken out to obtain the twin crystal copper material, also called as an annealed twin crystal plating material.

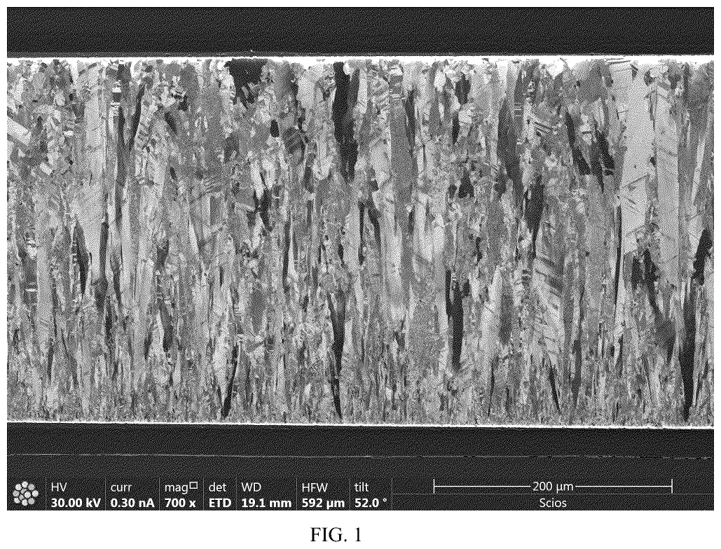

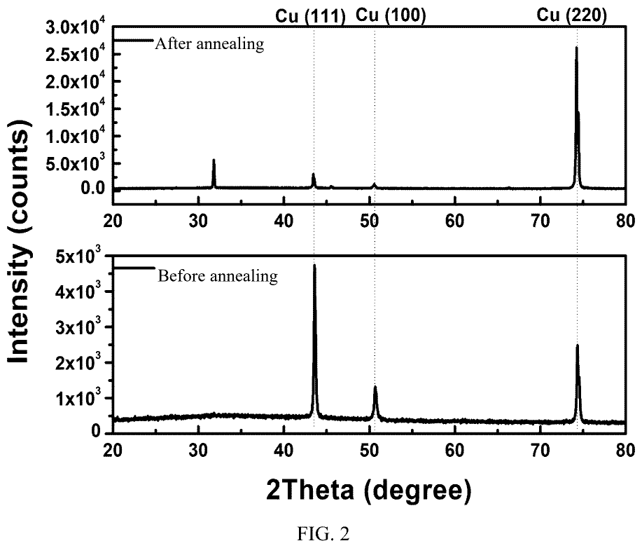

The obtained plating layer cross-sectional focused ion beam microscopic topography and surface X-ray diffraction pattern are shown in FIG. 1 and FIG. 2. The thickness of the plating layer is 310 μm, columnar grains are mainly formed parallel to the growth direction, and no crystal grain growing up abnormally is observed. Nanoscale twin crystal lamellas and the growth direction of the plating layer forms an angle of 45 degrees, and a proportion of crystal grains with the nanoscale twin crystal lamellas in total crystal grains of the plating layer is more than 90%. The plating layer has the preferred orientation of a (220) crystal plane (namely, a (110) crystal plane), and an intensity ratio of (220)/(111) diffraction peaks is more than 9.

### Example 2

The present example provides a twin crystal copper material, which is prepared by the following method. The method includes the following steps:

### (1) Preparation of a Plating Solution

The electroplating solution is prepared and uniformly dispersed by adopting the following components of 40 g/L of copper ions, 40 g/L of sulfuric acid, 40 ppm of chloride ions, 100 ppm of an inhibitor, 500 ppm of an auxiliary agent and 250 mL of pure water, wherein the inhibitor is gelatin with a coagulation value of 100 bloom, and the auxiliary agent is sodium octadecyl sulfonate.

### (2) Direct Current Electroplating

a. Cathode pretreatment. A high-purity titanium plate is used as a cathode, and subjected to the processes of alkali washing, acid washing and water washing sequentially.

b. Direct current electroplating. The titanium plate as the cathode and phosphor copper as an anode (a phosphor content is 0.05 wt %) are immersed in the plating solution, magnetic stirring is carried out at 300 rpm, and the plating solution is controlled to be constant at 30° C. Then, a rectifier is connected in, and electroplating is carried out for 20 min at a current density of 3 A/dm2.

c. Plating layer post-treatment. A plating layer is taken out from the plating solution, separated from a substrate (titanium plate), and repeatedly washed by using pure water to remove a residual plating solution, and finally the surface of the plating layer is dried by using compressed air.

### (3) Annealing Treatment.

The plating layer is put in a tube furnace, a nitrogen protective atmosphere is introduced, the temperature in the furnace is increased from the room temperature to 2000° C. at the speed of 10° C./min and kept for 1 hour, then the furnace is naturally cooled, and the plating layer is taken out to obtain the twin crystal copper material, also called as an annealed twin crystal plating material.

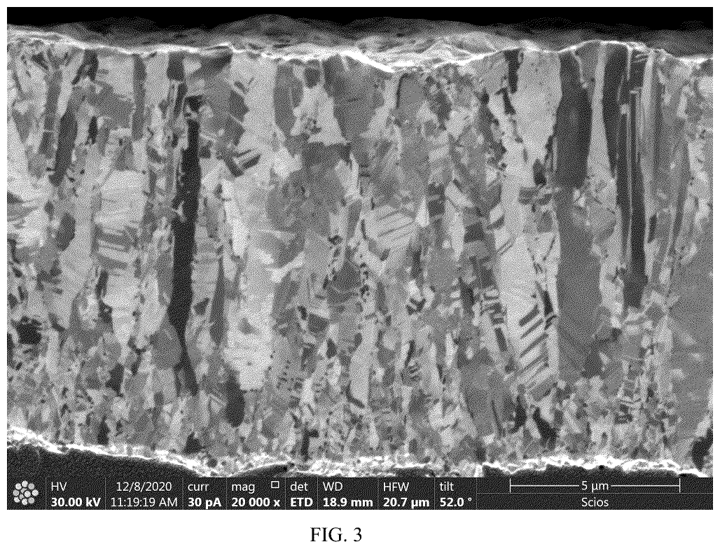

The obtained plating layer cross-sectional focused ion beam microscopic topography is shown in FIG. 3. The thickness of the plating layer is 15 μm, columnar grains are mainly formed parallel to the growth direction, and no crystal grain growing up abnormally is observed. Nanoscale twin crystal lamellas and the growth direction of the plating layer forms an angle of 45 degrees, and a proportion of crystal grains with the nanoscale twin crystal lamellas in total crystal grains of the plating layer is more than 50%.

### Example 3

This example differs from Example 2 in that in step (3), the furnace is heated from the room temperature to 400° C. at 10° C./min and kept for 1 hour.

Tests show that preferred orientation is enhanced along with the increase of the annealing temperature to 400° C., the twin crystal proportion is correspondingly improved, and abnormal growth of crystal grains is not seen, so that the thermal stability is excellent.

### Comparative Example 1

### (1) Preparation of a Plating Solution

The electroplating solution is prepared and uniformly dispersed by adopting the following components of 40 g/L of copper ions, 40 g/L of sulfuric acid, 40 ppm of chloride ions, 100 ppm of an inhibitor, and 250 mL of pure water, without an auxiliary agent, wherein the inhibitor is gelatin with a coagulation value of 100 bloom.

### (2) Direct Current Electroplating

a. Cathode pretreatment. A high-purity titanium plate is used as a cathode, and subjected to the processes of alkali washing, acid washing and water washing sequentially.

b. Direct current electroplating. The titanium plate as the cathode and phosphor copper as an anode (a phosphor content is 0.05 wt %) are immersed in the plating solution, magnetic stirring is carried out at 300 rpm, and the plating solution is controlled to be constant at 30° C. Then, a rectifier is connected in, and electroplating is carried out for 30 min at a current density of 3 A/dm2.

c. Plating layer post-treatment. A plating layer is taken out from the plating solution, separated from a substrate, and repeatedly washed by using pure water to remove a residual plating solution, and finally the surface of the plating layer is dried by using compressed air to obtain a growth twin crystal plating layer.

This comparative example is different from Example 2 in that no auxiliary agent is contained in the plating solution and no annealing treatment is performed.

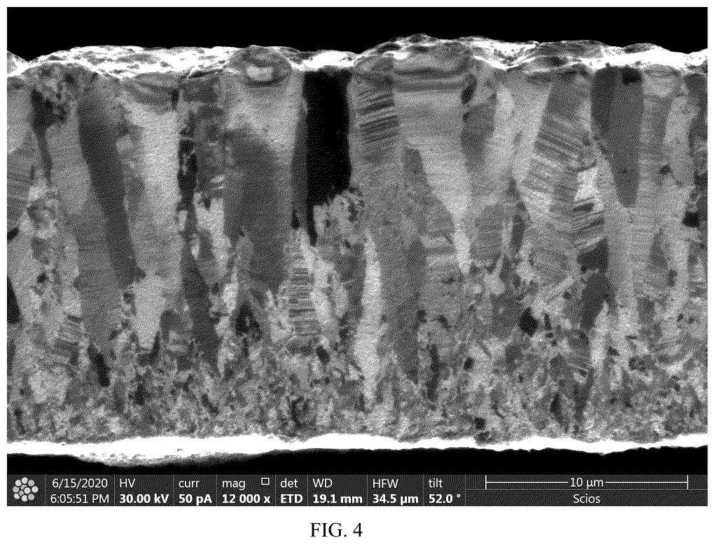

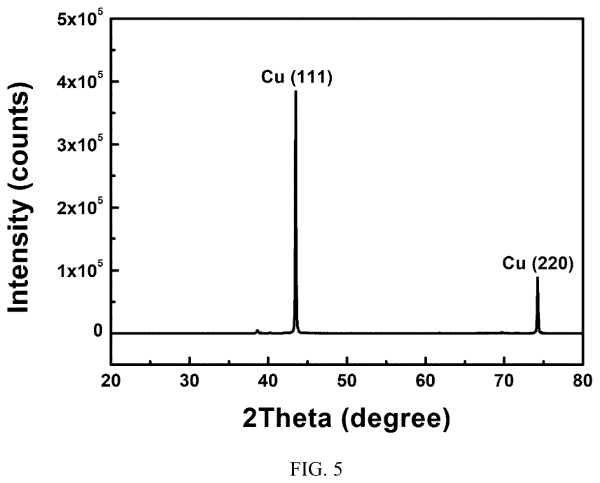

The obtained plating layer cross-sectional focused ion beam microscopic topography and surface X-ray diffraction pattern are shown in FIG. 4 and FIG. 5. The thickness of the plating layer is 18 μm, and columnar grains are mainly formed parallel to the growth direction. High-density growth twin crystal lamellas are perpendicular to the growth direction of the plating layer, and a proportion of crystal grains with the high-density nanoscale twin crystal lamellas in total crystal grains of the plating layer is more than 70%.

In conclusion, the twin crystal copper material provided by the present invention is annealed twin crystal copper with preferred orientation of the (110) crystal plane, wherein a high-proportion twin crystal boundary exists stably, compared with electroplated micron twin crystal copper with highly preferred orientation of the (110) crystal plane, the twin crystal copper material has more excellent structure thermal stability, the crystal grains grow up normally within a common heat treatment temperature range, and the twin crystal copper material shows the unique property that the proportion of the twin crystal lamellas does not decrease but increases.

The method of the present invention has the advantages of easy operation, low cost, strong practicability, suitability for industrialized popularization and the like, can be suitable for the electroplated copper related fields represented by the manufacturing and packaging of integrated circuits and circuit boards, and optimizes the stability of a heat treatment structure of the electroplated copper material.

In the field of microelectronic packaging, a 2.5D or 3D packaging technology can stack two or more chips or wafers in a bump bonding manner, so that three-dimensional arrangement of the chips is realized, the signal transmission distance is remarkably reduced, and high-speed transmission and low power consumption are realized. The bonding technology, one of the key technologies, is essential to ensure reliable electrical connection and mechanical support between the chips. The electroplated copper micro-nano structure and the thermal stability thereof are important factors influencing the normal-temperature and high-temperature mechanical properties of the material. Because the manufacturing process involves a plurality of high-temperature treatment procedures such as resin solidification, and solder welding, the electroplated copper inevitably generates crystal boundary migration and crystal grain growth under the action of recrystallization, generally causing the reduction of material intensity. Common bonding methods are oxide bonding, solder bonding, copper-copper bonding, organic polymer bonding, and hybrid bonding. The hybrid bonding is carried out by filling gaps among the bumps with a dielectric layer and bonding the bumps with each other while copper-copper bonding is carried out. Compared with other methods, the hybrid bonding effectively improves the bonding force between the chips and can ensure better electrical connection, thereby having better application prospects. However, the copper bumps are easily recrystallized in the thermocompression bonding process and during the subsequent processes such as reflow soldering or heat treatment, so that the mechanical intensity of the copper bumps is reduced, thereby increasing the failure risk of the device. In order to solve the above problems, the present invention also provides a hybrid bonding structure and a preparation method therefor.

### Example 4

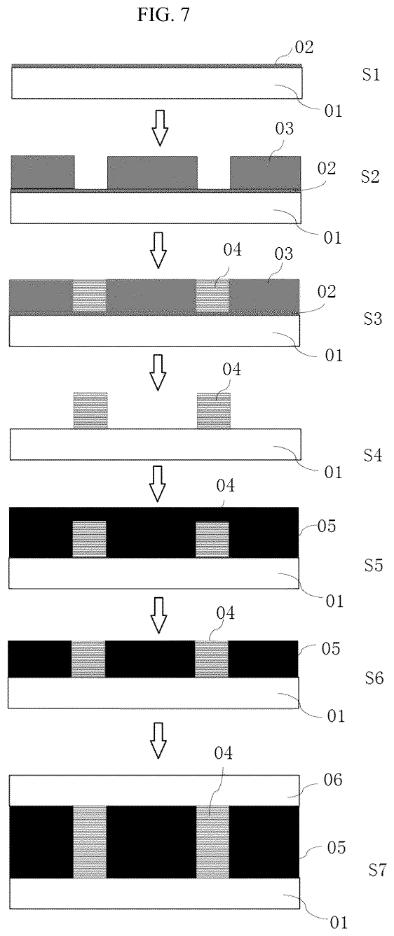

This example provides a hybrid bonding structure and a preparation method therefor. As shown in FIG. 7, the preparation method includes the following steps:

S1: An adhesion layer of titanium and a seed layer of copper are deposited on an upper surface of a first substrate 01 to form a composite layer 02 of the adhesion layer and the seed layer, wherein thicknesses of the adhesion layer and the seed layer are respectively 100 nm and 400 nm.

S2: A layer of photoresist 03 which is 15 microns thick is coated on the upper surface of the composite layer 02 of the adhesive layer and the seed layer in a spin-coating manner, and exposure and development are carried out to pattern at a specific position of the first substrate 01 so as to expose the composite layer 02 of the adhesive layer and the seed layer.

S3: Filling of first copper bumps 04 is carried out by using a direct current electroplating process, wherein the plating layer height of the first copper bumps 04 is 15 microns.

The direct current electroplating process includes:

### (a) Preparation of a Plating Solution

The electroplating solution is prepared and uniformly dispersed by adopting the following components of 30 g/L of copper ions, 50 g/L of sulfuric acid, 30 ppm of chloride ions, 100 ppm of gelatin (a coagulation value is 200 bloom), 100 ppm of sodium polyvinyl sulfonate (a molecular weight is 50000), and water.

### (b) Direct Current Electroplating

A titanium plate as a cathode and high-purity phosphor copper as an anode (a phosphor content is 0.04 wt %) are immersed in the plating solution, and the plating solution is controlled to be constant at 25° C. Then, a rectifier is connected in, and electroplating is carried out at a current density of 3 A/dm2.

S4: A photoresist 03 is removed by using a photoresist removing solution, and the composite layer 02 of the adhesion layer and the seed layer is removed by using a wet etching method.

S5: The upper surface of the first substrate 01 is covered with a polyimide dielectric layer 05 by using a spin-coating method, wherein the thickness of the polyimide dielectric layer 05 is 20 microns, and then semi-curing treatment is carried out on the polyimide dielectric layer 05.

S6: The upper surface of the polyimide dielectric layer 05 is polished by using CMP until the upper surface of the first copper bumps 04 is exposed. The polishing is continued so that the first copper bumps 04 and the polyimide dielectric layer 05 are coplanar and achieve lower roughness. After the CMP, the upper surfaces of the first copper bumps 04 and the polyimide dielectric layer 05 are subjected to plasma cleaning in order to clean and activate bonding surfaces. The plasma cleaning parameters are hydrogen 70 sccm, oxygen 20 sccm, power 500 W and time 360 s.

S7: The above steps are repeated on the upper surface of a second substrate 06, then corresponding bonding positions of the second substrate 06 and the first substrate 01 are aligned, and bonding between the copper bumps and adhesion between dielectric layers are carried out in a nitrogen atmosphere. The bonding parameters are heating temperature 300° C., applied pressure intensity 1 MPa, and heating time 1 hour. The bonding process is also a process of annealing the first copper bumps 04, so that an annealed twin crystal structure is formed in the first copper bumps 04 after the bonding is completed.

After the process is completed, the shear intensity test and the temperature cycle test are carried out on the bonding points, and the result shows that the shear intensity of the bonding points prepared according to this example is 38 MPa, and the increase rate of the contact resistance is less than 10% after the bonding points are cycled for 1000 times from −55° C. to 70° C.

### Example 5

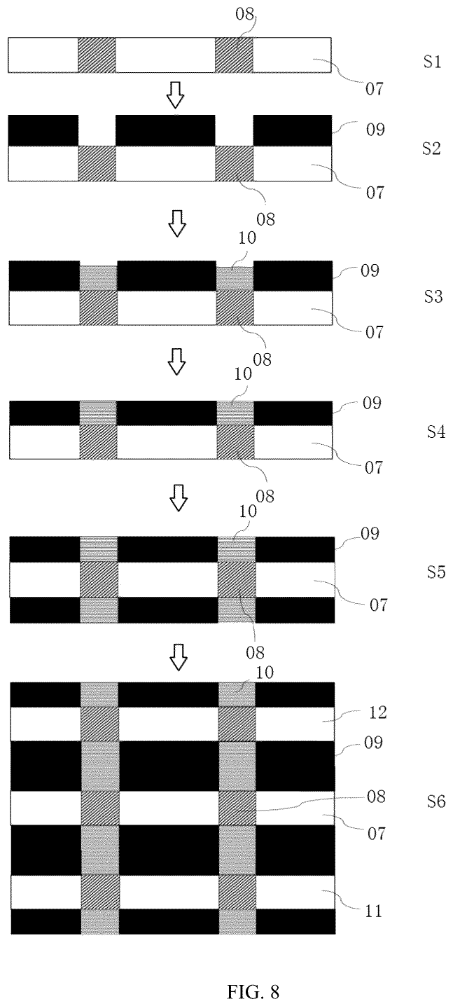

This example provides a hybrid bonding structure and a preparation method therefor. As shown in FIG. 8, the preparation method includes the following steps:

S1: A first silicon substrate 07 with a TSV structure of a diameter of 60 microns and a depth of 300 microns is prepared. The TSV is filled with a conductive metal 08 made of copper.

S2: A benzocyclobutene dielectric layer 09 is coated on one surface of the first silicon substrate 07 in a spin-coating manner, wherein the thickness of the benzocyclobutene dielectric layer 09 is 60 microns. Windowing is carried out at the position with the TSV structure by using a photoetching technology, to expose the surface of the conductive metal 08.

S3: Second copper bumps 10 are electroplated on the surface of the conductive metal 08, to ensure that the plating layer height of the second copper bumps 10 is 60 microns.

The electroplating process includes the following steps:

### (a) Preparation of a Plating Solution

The electroplating solution is prepared and uniformly dispersed by the following components of 50 g/L of copper ions, 150 g/L of sulfuric acid, 70 ppm of chloride ions, 20 ppm of gelatin (a coagulation value is 100 bloom), 300 ppm of sodium polystyrene sulfonate (a molecular weight is 40000), and water.

### (b) Direct Current Electroplating

A titanium plate as a cathode and high-purity phosphor copper as an anode (a phosphor content is 0.07 wt %) are immersed in the plating solution, and the plating solution is controlled to be constant at 25° C. Then, a rectifier is connected in, and electroplating is carried out at a current density of 6 A/dm2.

S4: CMP treatment is directly carried out on the upper surfaces of the second copper bumps 10 and the benzocyclobutene dielectric layer 09 to make the second copper bumps 10 and the benzocyclobutene dielectric layer 09 coplanar and achieve lower roughness because no redundant photoresist and conductive layer exists on the surface of the first silicon substrate 07. After the CMP is finished, plasma cleaning is carried out on the upper surfaces of the second copper bumps 10 and the benzocyclobutene dielectric layer 09, wherein the parameters are hydrogen 60 sccm, oxygen 30 sccm, power 700 W and time 180 s.

S5: The above steps are repeated on the other surface of the first silicon substrate 07 to obtain a vertically symmetrical structure.

S6: Steps S1-S4 are repeated for a second silicon substrate 11 and a second silicon substrate 12, respectively, then corresponding bonding positions of the first silicon substrate 07, the second silicon substrate 11 and the second silicon substrate 12 are aligned, and bonding is carried out in a nitrogen atmosphere. The bonding parameters are heating temperature 200° C., applied pressure intensity 2 MPa, and heating time 2 hour.

After the process is completed, the shear intensity test and the temperature cycle test are carried out on the bonding points, and the result shows that the shear intensity of the bonding points prepared according to this example is 45 MPa, and the increase rate of the contact resistance is less than 10% after the bonding points are cycled for 1000 times from −55° C. to 70° C.

### Example 6

This example differs from Example 4 in that the heating temperature in the bonding parameters is 400° C.

Along with the increase of the annealing temperature, the proportion of annealed twin crystals is increased, crystal grains do not grow obviously, and the intensity and the toughness of bumps are improved.

After the process is completed, the shear intensity test and the temperature cycle test are carried out on the bonding points, and the result shows that the shear intensity of the bonding points prepared according to this example is 50 MPa, and the increase rate of the contact resistance is less than 10% after the bonding points are cycled for 1000 times from −55° C. to 70° C.

### Comparative Example 2

This comparative example is identical to steps S1-S2 and S4-S7 of Example 4, except that:

1. The direct current electroplating process in S3 includes:

### (a) Preparation of a Plating Solution

The electroplating solution is prepared and uniformly dispersed by the following components of 50 g/L of copper ions, 100 g/L of sulfuric acid, 50 ppm of chloride ions, 10 ppm of SPS, 200 ppm of polyethylene glycol, 20 ppm of Janus green, and water.

### (b) Direct Current Electroplating

A titanium plate as a cathode and high-purity phosphor copper as an anode (a phosphor content is 0.04 wt %) are immersed in the plating solution, and the plating solution is controlled to be constant at 25° C.

Then, a rectifier is connected in, and electroplating is carried out at a current density of 3 A/dm2.

2. The bonding points do not form an annealed twin crystal structure in S7.

After the process is completed, the shear intensity test and the temperature cycle test are carried out on the bonding points, and the result shows that the shear intensity of the bonding points prepared according to this comparative example is 22 MPa, and the contact resistance is increased by 10-20% after the bonding points are cycled for 1000 times from −55° C. to 70° C.

In conclusion, the hybrid bonding structure provided by the present invention can effectively improve the bonding force between chips, and can ensure better electrical connection, the copper bonding points have excellent structure thermal stability and mechanical properties (especially the high-temperature mechanical property), the hybrid bonding structure has high mechanical intensity and toughness, and the service reliability is improved.

The use of the copper bonding points with the specific composition avoids the recrystallization of the copper bonding points in the thermocompression bonding process and the subsequent processes such as reflow soldering or heat treatment, thereby solving the problems of insufficient mechanical intensity, poor service reliability and the like caused by the recrystallization.

What is claimed is:

1. A twin crystal copper material, wherein the twin crystal copper material has preferred orientation of a (110) crystal plane, the twin crystal copper material comprises a twin crystal structure, the twin crystal structure comprises twin crystal lamellas, and the twin crystal lamellas are mainly distributed at an included angle of 45 degrees with a crystal grain growth direction; and a proportion of crystal grains with the twin crystal lamellas in total crystal grains of the twin crystal copper material is more than or equal to 50%, and/or a ratio of a volume of the twin crystal structure to a total volume of the twin crystal copper material is more than or equal to 50%.

2. The twin crystal copper material according to claim 1, wherein XRD diffraction analysis is carried out on the twin crystal copper material, and an intensity ratio of (220)/(111) diffraction peaks is more than 2.

3. The twin crystal copper material according to claim 1, wherein the twin crystal copper material is obtained by carrying out heat treatment on a pre-electroplated copper material with preferred orientation of a (111) crystal plane, and a heat treatment temperature is more than or equal to 200° C.

4. A preparation method for the twin crystal copper material according to claim 1, wherein the preparation method comprises the following steps:
(1) preparing a plating solution
the plating solution comprising copper ions, sulfuric acid, chloride ions, an additive and water, the additive comprising an inhibitor and an auxiliary agent, and the auxiliary agent being at least one selected from organic sulfonates;
(2) carrying out direct current electroplating
immersing an anode and a cathode as a conductive substrate into the plating solution, and electroplating to obtain a pre-electroplated copper material; and
(3) carrying out heat treatment on the pre-electroplated copper material with a heat treatment temperature of more than or equal to 200° C., to obtain the twin crystal copper material.

5. The preparation method for the twin crystal copper material according to claim 4, wherein
in step (1), the organic sulfonates comprise at least one of polystyrene sulfonate, polyethylene sulfonate, alkyl sulfonate and alkylbenzene sulfonate, a molecular weight of the polystyrene sulfonate and a molecular weight of the polyethylene sulfonate are independently 1000-100000, and carbon atom numbers of the alkyl sulfonate and the alkylbenzene sulfonate are more than or equal to 12;
in step (1), a concentration of the auxiliary agent in the plating solution is 10-500 ppm;
in step (1), the inhibitor is gelatin, and a coagulation value of the gelatin is 10-300 bloom;
in step (1), a concentration of the inhibitor in the plating solution is 5-200 ppm;
in step (1), a concentration of the copper ions in the plating solution is 20-70 g/L;
in step (1), a concentration of the sulfuric acid in the plating solution is 20-200 g/L;
in step (1), a concentration of the chloride ions in the plating solution is 20-80 ppm;
in step (2), the anode is selected from a phosphor-copper anode, and a phosphor content in the phosphor-copper anode is 0.03-0.075 wt %;
in step (2), an electroplating temperature is 20-50° C.;
in step (2), the electroplating is carried out under a constant temperature condition;
in step (2), a current density of the electroplating is 0.5-25 A/dm²;
in step (2), an electroplating time is 20-1800 min;
the electroplating solution is further stirred in the electroplating process in step (2), wherein the stirring comprises at least one of circulating jet flow, air stirring, magnetic stirring and mechanical stirring; and
the heat treatment in step (3) comprises annealing treatment, comprising heating the pre-electroplated copper material from a room temperature to the heat treatment temperature of 200-750° C. in an inert atmosphere, preserving the heat for 20-1200 min, and finally recovering the room temperature, wherein a heating rate is 1-50° C./min.

6. The preparation method for the twin crystal copper material according to claim 5, wherein the method comprises the following steps:
(1) preparing the plating solution
dissolving copper salt, the sulfuric acid, chloride, the inhibitor and the auxiliary agent in water, and fully and uniformly dispersing to obtain the plating solution, wherein the plating solution comprises 20-70 g/L of the copper ions, 20-200 g/L of the sulfuric acid, 20-80 ppm of the chloride ions, 5-200 ppm of the inhibitor, 10-500 ppm of the auxiliary agent and the balance of water, the inhibitor comprises gelatin, and the auxiliary agent is at least one selected from the organic sulfonates;
(2) carrying out direct current electroplating
immersing the anode and the cathode as the conductive substrate into the plating solution, and electroplating at a constant current under a temperature of 20-50° C. to obtain the pre-electroplated copper material, wherein the current density is 0.5-25 A/dm², and the electroplating time is 20-1800 min; and
(3) heating the pre-electroplated copper material until the temperature is more than or equal to 200° C. and keeping the temperature for 20-1200 min, to obtain the twin crystal copper material.

7. A hybrid bonding structure, wherein the hybrid bonding structure comprises a first substrate and a second substrate which are oppositely disposed, a first bonding layer is disposed on the first substrate, a second bonding layer is disposed on the second substrate, and the first bonding layer and the second bonding layer are bonded to form a bonding interface; and
copper bonding points are disposed in the first bonding layer and/or the second bonding layer, and the copper bonding points are the twin crystal copper material according to claim 1.

8. The hybrid bonding structure according to claim 7, wherein
a height of the copper bonding points is 0.5-500 microns;
materials of the first substrate and the second substrate independently comprise silicon, a compound, ceramic or glass;
the first bonding layer comprises a dielectric layer and copper bonding points disposed in the dielectric layer at intervals, and the copper bonding points are exposed out of a surface of the first bonding layer for bonding;
the second bonding layer comprises a dielectric layer and copper bonding points disposed in the dielectric layer at intervals, and the copper bonding points are exposed out of a surface of the second bonding layer for bonding; and
materials of the dielectric layer in the first bonding layer and the dielectric layer in the second bonding layer are independently selected from at least one of organic polymers or oxides.
